(19) United States
(12) Patent Application Publication
(10) Pub. No.: US 2022/0415625 A1
(43) Pub. Date: Dec. 29, 2022

(54) SUBSTRATE SUPPORTS WITH INTEGRATED RF FILTERS

(71) Applicant: LAM RESEARCH CORPORATION, Fremont, CA (US)

(72) Inventors: Sunil KAPOOR, Vancouver, WA (US); Dan MAROHL, San Jose, CA (US); Ramkishan Rao LINGAMPALLl, Danville, CA (US); Eric MADSEN, Sherwood, OR (US)

(21) Appl. No.: 17/780,347

(22) PCT Filed: Nov. 2, 2020
(86) PCT No.: PCT/US2020/058484

§ 371 Date: May 26, 2022

Related U.S. Application Data
(60) Provisional application No. 62/944,441, filed on Dec. 6, 2019.

(51) Int. Cl. H01J 37/32; H03H 7/01; H05B 1/02; C23C 16/458; C23C 16/509; C23C 16/455; C23C 14/50

(52) U.S. Cl. CPC H01J 37/32724; H03H 7/0115; H01J 37/32091; H05B 1/0233; C23C 16/4586; C23C 16/5096; C23C 16/45536; C23C 14/50; H01L 21/6833

(57) ABSTRACT

A substrate support including a body, a heating element, a first radio frequency filter, and a second radio frequency filter. The body is configured to support a substrate. The heating element is at least partially implemented in a first portion of the body. The first radio frequency filter is connected to an input of the heating element and at least partially implemented in a second portion of the body and connected to the heating element by a first via. The second radio frequency filter is connected to an output of the heating element and at least partially implemented in the second portion or a third portion of the body.

### CROSS-REFERENCE TO RELATED APPLICATIONS

This application claims the benefit of U.S. Provisional Application No. 62/944,441, filed on Dec. 6, 2019. The entire disclosure of the application referenced above is incorporated herein by reference.

### FIELD

The present disclosure relates to pedestals for supporting a substrate during processing.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate support (e.g., a pedestal or electrostatic chuck) includes a body. Electrostatic clamping and radio frequency (RF) electrodes and one or more heater elements are disposed in the body. Power is supplied to the heater elements via a filter box, which is external to the substrate support. The filter box includes RF filters that are connected via cables to leads in a support column of the substrate support. The leads are connected to the heating elements.

The RF filters in the filter box are utilized to prevent RF leaking from the RF electrodes through the heating elements to ground. RF leaking can occur due to the heating elements being in close proximity to the RF electrodes and RF coupling between the heating elements and the RF electrodes.

### SUMMARY

A substrate support is provided and includes a body, a heating element, a first radio frequency filter, and a second radio frequency filter. The body is configured to support a substrate. The heating element is at least partially implemented in a first portion of the body. The first radio frequency filter is connected to an input of the heating element and at least partially implemented in a second portion of the body and connected to the heating element by a first via. The second radio frequency filter is connected to an output of the heating element and at least partially implemented in the second portion or a third portion of the body.

In other features, the first portion is a first one or more layers of the body. The second portion is a second one or more layers of the body. The third portion is a third one or more layers of the body.

In other features, the first radio frequency filter is configured to filter out one or more radio frequencies. The second radio frequency filter is configured to filter out the one or more radio frequencies.

In other features, the first radio frequency filter is configured to filter out a first one or more radio frequencies. The second radio frequency filter is configured to filter out a second one or more radio frequencies. The first one or more radio frequencies are not exclusive of the second one or more radio frequencies.

In other features, the first radio frequency filter includes a first inductor. The second radio frequency filter includes a second inductor. In other features, the first inductor and the second inductor are formed of at least one of a nickel alloy, a platinum alloy, a rhodium alloy, an iridium alloy, a gold nickel alloy, a copper nickel alloy, a copper tungsten alloy or a palladium alloy. In other features, the first radio frequency filter has a first capacitance. The second radio frequency filter has a second capacitance.

In other features, the first radio frequency filter includes a first capacitor having the first capacitance. The first capacitor is connected in parallel with the first inductor. The second radio frequency filter includes a second capacitor having the second capacitance, where the second capacitor is connected in parallel with the second inductor. The first inductor is connected in parallel with a first capacitor, which is disposed external to the substrate support. The second inductor is connected in parallel with a second capacitor, which is disposed external to the substrate support.

In other features, the substrate support further includes: a third inductor connected to the first inductor, where the first inductor and the third inductor are arranged to have the first capacitance. A fourth inductor connected to the second inductor, where the second inductor and the fourth inductor are arranged to have the second capacitance.

In other features, the first radio frequency filter includes a first capacitor having the first capacitance. The second radio frequency filter includes a second capacitor having the second capacitance. The first capacitor includes multiple conductive elements implemented in two layers of the body. The second capacitor includes multiple conductive elements implemented in two layers of the body. In other features, the body includes a clamping electrode and a radio frequency electrode.

In other features, the first radio frequency filter includes a first capacitor and the second radio frequency filter includes a second capacitor. In other features, the first capacitor and the second capacitor are formed of at least one of a nickel alloy, a platinum alloy, a rhodium alloy, an iridium alloy, a gold nickel alloy, a copper nickel alloy, a copper tungsten alloy or a palladium alloy.

In other features, a system is provided and includes the substrate support and a power source. The power source supplies power to the heating element and is connected to the heating element, the first radio frequency filter and the second radio frequency filter by conductive elements. In other features, the system further includes a filter box including a first capacitor and a second capacitor. The first radio frequency filter includes a first inductor. The second radio frequency filter includes a second inductor. The first capacitor is connected to the input of the heating element and the first inductor by a first via. The second capacitor is connected to the output of the heating element and the second inductor by a second via.

In other features, a system is provided and includes a substrate support, a first heating element, a first radio frequency filter, a second radio frequency filter and a power source. The substrate support includes layers. The first heating element is implemented in a first one or more of the layers. The first radio frequency filter is implemented in a second one or more of the layers. The second radio frequency filter is implemented a third one or more of the plurality of layers. The first radio frequency filter, the heating element and the second radio frequency filter are connected in series. The power source supplies power to the first radio frequency filter to heat the substrate support. The power source receives return power back from the second radio frequency filter.

In other features, the substrate support further includes a second heating element, a third radio frequency filter, and a fourth radio frequency filter. The second heating element, the third radio frequency filter and the fourth radio frequency are connected in series and receive power from the power source.

In other features, the second one or more of the layers is not exclusive of the third one or more of the layers. In other features, the first radio frequency filter and the second radio frequency filter are implemented in only one of the layers of the substrate support. In other features, the first radio frequency filter and the second radio frequency filter are implemented in three or five of the layers.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system including a substrate support including a radio frequency (RF) filter in accordance with an example of the present disclosure;

FIG. 2 is a cross-sectional side view of an example of the substrate support of FIG. 1;

FIG. 3 is a cross-sectional side view of an example of another substrate support including conductive elements of RF filters implemented in a single layer in accordance with an example of the present disclosure;

FIG. 4 is a cross-sectional side view of an example of another substrate support including conductive elements of RF filters implemented in two layers in accordance with an example of the present disclosure;

FIG. 5 is a cross-sectional side view of an example of another substrate support including conductive elements of RF filters implemented in three layers in accordance with an example of the present disclosure; and

FIG. 6 is a cross-sectional top view of a portion of the substrate support of FIG. 5 illustrating an example heating element, inductors and corresponding vias.

In the drawings, reference numbers may be reused to identify similar and/or identical elements.

### DETAILED DESCRIPTION

Power is fed to heating elements in a pedestal via a RF filter box. The RF filter box is connected to a pedestal and includes multiple RF filters. The RF filters typically include inductors and capacitors with a large envelope. The RF filter components in the RF filter box are too large and are not configured and/or formed of materials suitable to be integrated into a pedestal.

RF filter boxes are typically installed under a pedestal and connected to the pedestal via cables. Space available under a pedestal is typically limited. This poses installation and maintenance issues. Also, the RF filter box can be a primary source of RF radiation. This is due to RF coupling between RF electrodes and heating elements in the pedestal. RF energy can be transferred from the RF electrodes to the heating elements, which is then transferred to the RF filter box. In addition, RF radiation variability is high in the RF filter box due to proximity between components and flexible cables used to connect the RF filter box to the pedestal. The RF variability is associated with different amounts of power being coupled between RF electrodes and heating elements, which changes RF radiation. The RF variability is also associated with changes in positions of parts (e.g., cables), which changes capacitances and as a result changes RF radiation. Additional RF variability can exist due differences in manufacturing of RF components.

The examples set forth herein include substrate supports with integrated RF filters. The RF filters are sized and formed of materials suitable for being implemented within a substrate support and filtering high frequency coupling from current passing through heating elements. An RF filter is integrated into the substrate supports for each input and output leg of each heating element. As a result, each of the heating elements has multiple RF filters. This prevents RF leaking to ground and/or to a power source. The substrate supports are fabricated to include the RF filters.

By integrating the RF filters into the substrate supports, RF filters for heating elements are no longer needed in RF filter boxes external to the substrate supports. This frees up space external to and/or underneath the substrate supports for other purposes. In some example embodiments, an RF filter box is not used and power is supplied directly to the substrate supports. No additional high RF filtering is needed external to the substrate supports. This eliminates the RF coupling to ground and/or a power source via the RF filter box and RF radiation variability associated with a RF filter box. In some embodiments, the integrated filters include printed components having tight tolerances, which further minimizes RF radiation variability.

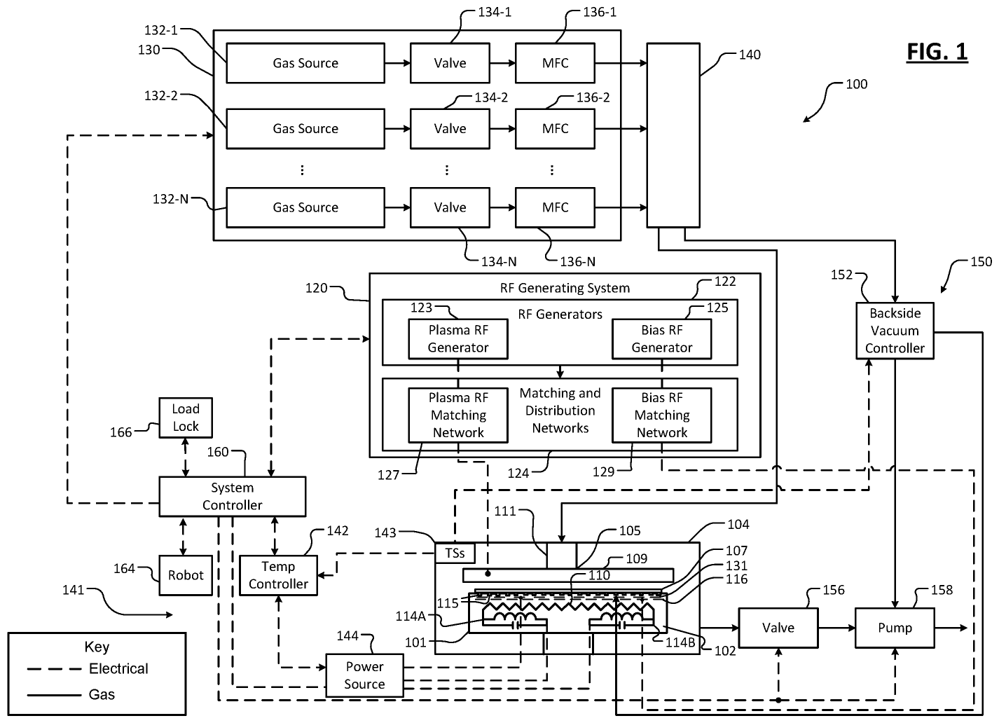

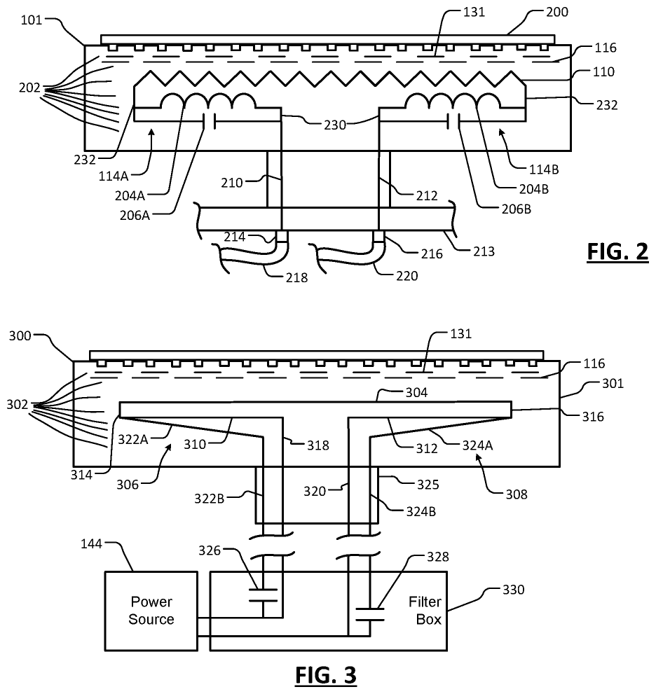

FIG. 1 shows a substrate processing system 100 that includes a substrate support 101, shown as an electrostatic chuck. The substrate support 101 may be configured the same or similarly as any of the substrate supports disclosed herein including that shown in FIGS. 2-6. Although FIG. 1 shows a capacitive coupled plasma (CCP) system, the embodiments disclosed herein are applicable to transformer coupled plasma (TCP) systems, inductively coupled plasma (ICP) systems and/or other systems and plasma sources that include a substrate support. The embodiments are applicable to plasma enhanced chemical vapor deposition (PECVD) processes, chemically enhanced plasma vapor deposition (CEPVD) processes, atomic layer deposition (ALD) processes, and/or other processes in which substrate temperatures are greater than or equal to 450° C. In the example shown, the substrate support 101 includes a monolithic anisotropic body 102. The body 102 may be formed of different materials and/or different ceramic compositions. The body 102 may include, for example, aluminum nitride (AlN₃), aluminum oxide (Al₂O₃), and/or aluminum oxynitride (AlON).

The substrate processing system 100 includes a processing chamber 104. The substrate support 101 is enclosed within the processing chamber 104. The processing chamber 104 also encloses other components, such as an upper electrode 105, and contains RF plasma. During operation, a substrate 107 is arranged on and electrostatically clamped to the substrate support 101. For example only, the upper electrode 105 may include a showerhead 109 that introduces and distributes gases. The showerhead 109 may include a stem portion 111 including one end connected to a top surface of the processing chamber 104. The showerhead 109 is generally cylindrical and extends radially outward from an opposite end of the stem portion 111 at a location that is spaced from the top surface of the processing chamber 104. A substrate-facing surface of the showerhead 109 includes holes through which process or purge gas flows. Alternately, the upper electrode 105 may include a conducting plate and the gases may be introduced in another manner.

The substrate support 101 may include temperature control elements (TCEs) also referred to as heating elements. As an example, FIG. 1 shows the substrate support 101 including a heating element 110. The heating element 110 receives power and heats the substrate support 101. The substrate support 101 also includes RF filters 114 (identified as 114A and 114B). The RF filters 114 are connected to the inlet and outlet legs of the heating element 110. The example heating element and RF filter configuration of FIG. 1 is further described below with respect to FIG. 2. Other integrated heating element and RF filter examples are described with respect to FIGS. 3-6. In an embodiment, the substrate support 101 includes one or more gas channels 115 for flowing backside gas to a backside of the substrate 107.

An RF generating system 120 generates and outputs RF voltages to the upper electrode 105 and one or more lower electrodes 116 in the substrate support 101. One of the upper electrode 105 and the substrate support 101 may be DC grounded, AC grounded or at a floating potential. For example only, the RF generating system 120 may include one or more RF generators 122 (e.g., a capacitive coupled plasma RF power generator, a bias RF power generator, and/or other RF power generator) that generate RF voltages, which are fed by one or more matching and distribution networks 124 to the upper electrode 105 and/or the substrate support 101. An electrode that receives an RF signal, an RF voltage and/or RF power is referred to as a RF electrode. As an example, a plasma RF generator 123, a bias RF generator 125, a plasma RF matching network 127 and a bias RF matching network 129 are shown. The plasma RF generator 123 may be a high-power RF generator producing, for example, 6-10 kilo-watts (kW) of power or more. The bias RF matching network supplies power to RF electrodes, such as RF electrodes 116.

A gas delivery system 130 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas and/or purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 104. For example only, the output of the manifold 140 is fed to the showerhead 109.

The substrate processing system 100 further includes a heating system 141 that includes a temperature controller 142, which may be connected to the heating element 110. The temperature controller 142 controls a power source 144, which supplies power to the heating element 110 via one of the RF filters 114. Although shown separately from a system controller 160, the temperature controller 142 may be implemented as part of the system controller 160. The substrate support 101 may include multiple temperature controlled zones, where each of the zones includes temperature sensors and heating elements. The temperature controller 142 may monitor temperatures as indicated by the temperature sensors and adjust current, voltage and/or power to the heating elements to adjust the temperatures to target temperatures. The power source 144 may also provide power, including a high voltage, to clamping electrodes 131 to electrostatically clamp the substrate 107 to the substrate support 101. Clamping electrodes receive power to electrostatically clamp down the substrate 107 to the substrate support 101 and may receive RF signals, RF voltages and/or RF power. The power source 144 may be controlled by the system controller 160.

The substrate processing system 100 further includes a cooling system 150 that includes a backside vacuum controller 152. The backside vacuum controller 152 may receive gas from the manifold 140 and supply the gas to the channels 115 and/or to a pump 158. This improves transfer of thermal energy between the substrate support 101 and the substrate 107. The backside gas may also be provided to improve substrate peripheral edge purging and vacuum tracking of a location of the substrate. The channels 115 may be fed by one or more injection ports. In one embodiment, multiple injection ports are included for improved cooling. As an example, the backside gas may include helium.

The temperature controller 142 may control operation and thus temperatures of heating elements and, as a result, temperatures of a substrate (e.g., the substrate 107). The temperature controller 142 controls current supplied to the heating elements based on detected parameters from temperature sensors 143 within the processing chamber 104. The backside vacuum controller 152 controls flow rate of backside gas (e.g., helium) to the gas channels 115 for cooling the substrate 107 by controlling flow from one or more of the gas sources 132 to the gas channels 115. The backside vacuum controller 152 controls pressure and flow rates of gas supplied to channels 115 based on detected parameters from the temperature sensors 143. In one embodiment, the temperature controller 142 and the backside vacuum controller 152 are implemented as a combined single controller.

The temperature sensors 143 may include resistive temperature devices, thermocouples, digital temperature sensors, and/or other suitable temperature sensors. During a deposition process, the substrate 107 may be heated in presence of high-power plasma. Flow of gas through the channels 115 may reduce temperatures of the substrate 107.

A valve 156 and the pump 158 may be used to evacuate reactants from the processing chamber 104. The system controller 160 may control components of the substrate processing system 100 including controlling supplied RF power levels, pressures and flow rates of supplied gases, RF matching, etc. The system controller 160 controls states of the valve 156 and the pump 158. A robot 164 may be used to deliver substrates onto, and remove substrates from, the substrate support 101. For example, the robot 164 may transfer substrates between the substrate support 101 and a load lock 166. The robot 164 may be controlled by the system controller 160. The system controller 160 may control operation of the load lock 166.

The valves, gas pumps, power sources, RF generators, etc. referred to herein may be referred to as actuators. The heating elements, gas channels, etc. referred to herein may be referred to as temperature adjusting elements.

The substrate support 101 may be a stratified and/or lamellar structure that includes a monolithic body 102. As an example, the substrate support 101 includes multiple layers including dielectric layers, heating element layers, intermediate layers with vias, inductor layers, capacitor layers, etc. Makeup and materials of the layers are further described below.

In the example shown, the electrodes 116, 131 are disposed in an uppermost one of the layers. The heating element 110 is disposed in another one of the layers. Although a single heating element 110 is shown, any number of heating elements may be included in the substrate support 101. The heating elements may have different sizes, shapes and provide corresponding heating patterns and be allocated to respective heating zones of the substrate support 101. A dielectric layer is disposed between the electrodes 116, 131 and the heating element 110. The RF filters 114 are disposed in additional layers below the heating element layer.

Although the substrate supports of FIGS. 1-6 are each shown as having certain features and not other features, each of the substrate supports may be modified to include any of the features disclosed herein and in FIGS. 1-6. The heating elements of the substrate supports may correspond to respective heating zones of the substrate supports. As an example, a substrate support may include two heating elements an inner heating element and an outer heating element. The out heating element may surround the inner heating element. This provides a ring-shaped outer zone and circular-shaped inner zone. The heating elements may be circular-shaped or have other geometric patterns.

FIG. 2 shows the substrate support 101 of FIG. 1 supporting a substrate 200. The substrate support 101 includes multiple layers, some of which are identified with numerical designator 202. The layers 202 include the electrodes 116, 131, the heating element 110, and the RF filters 114 (RF filters 114A and 114B are shown). Each of the RF filters 114 includes one or more inductors and/or one or more capacitors. In the example shown, the RF filters 114 include corresponding ones of inductors 204A, 204B and capacitors 206A, 206B. Intermediate dielectric layers are disposed (i) between the electrodes 116 and 131, (ii) between the electrodes 116 and the heating element 110, and (iii) between the inductors 204A, 204B and the capacitors 206A, 206B.

The inductor 204A is connected in parallel with the capacitor 206A. The inductor 204B is connected in parallel with the capacitor 206B. First ends of the inductor 204A and the capacitor 206A are connected to a first end of the heating element 110. Second ends of the inductor 204A and the capacitor 206A receive power from a power source (e.g., the power source 144) via a first conductive element 210. First ends of the inductor 204B and the capacitor 206B are connected to second ends of the heating element 110. Second ends of the inductor 204B and the capacitor 206B are connected to the power source 144 via a second conductive element 212. The conductive elements 210, 212 may extend from the substrate support 101 through a processing chamber wall 213 to connectors 214, 216, which are connected to cables 218, 220. The cables 218, 220 are connected to the power source 144. The cable 218 supplies power to the first RF filter 114A. The cable 220 returns power back from the second RF filter 1146 to the power source 144.

The RF filters 114 are much smaller in size than traditional RF filters included in RF filter boxes. The RF filters 114 are connected to one or more heating elements in the substrate support 101 and/or in other substrate supports disclosed herein. The RF filters may be of various types and have different configurations and conductive element patterns. The RF filters included in the substrate support 101 or in other disclosed substrate supports may be band reject, low pass and/or high pass filters. In one embodiment, multiple high frequency signals (e.g., a 13.56 mega-hertz (MHz) signal and a 27.12 MHz signal) are provided to the electrodes 116 and/or 131. The RF filters included in the substrate support 101 and/or in other disclosed substrate supports may operate as band reject filters and filter out the high frequency signals. The RF filters 114 may include tank filters, T-shape filters, L-shape filters, Pi-shape filters, etc. Each of the filters may include one or more inductors and one or more capacitors, only a single inductor, only a single capacitor, or have some other configuration. Although the inductors 204A, 204B and the capacitors 206A, 206B are shown as being implemented in single corresponding layers, each of the inductors 204A, 204B and capacitors 206A, 206B may be implemented in two or more layers of the substrate support 101. The inductors 204A, 204B may be winding elements having predetermined patterns.

The dielectric layers of the substrate support 101 may be formed of one or more ceramic compositions and may include, for example, aluminum nitride (AlN₃), aluminum oxide (Al₂O₃), and/or aluminum oxynitride (AlON). The conductive portions of the inductors 204A, 204B and the capacitors 206A, 206B may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys.

The inductors 204A, 204B and capacitors 206A, 206B may be formed on dielectric layers using various different processes. The inductors 204A, 204B and capacitors 206A, 206B may be bonded, brazed, printed and/or otherwise formed on dielectric layers. In one embodiment, the inductors 204A, 204B are formed using a silk screening process. In another embodiment, a sintering process is used during formation of the layers. In an embodiment, the capacitors 206A, 206B are formed using ceramic material and one or more of the above-stated alloys. For each of the capacitors 206A, 206B, the ceramic material is disposed between two conductive elements of the capacitors.

In the example shown, inner and outer conductive vias 230, 232 are used to connect the heating element 110 to the RF filters 114. The vias 230, 232 and/or other vias may be used to connect the inductors 204A, 20B to the capacitors 206A, 206B. The stated vias 230, 232 and the conductive elements 210, 212 may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys.

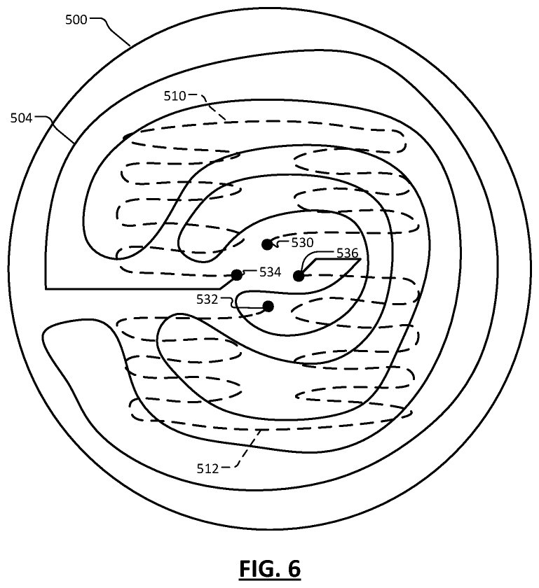

FIG. 3 shows a substrate support 300 including conductive elements of RF filters implemented in a single layer. The substrate support 300 includes a body 301 having multiple layers, some of which are identified with numerical designator 302. The layers 302 include the electrodes 116, 131, a heating element 304, and the RF filters 306, 308. Dielectric material is disposed between the electrodes 116, 131, the heating element 304, and conductive elements of the RF filters 306, 308, similar to that of the substrate support 101 of FIG. 2. The heating element 304 is implemented in a single layer and may have any winding pattern. The heating element 304 may have a similar winding as the heating element of FIG. 6 or other winding pattern. Although the heating element of FIG. 6 is shown having a particular pattern, the heating element may have other coiled and/or winding patterns.

Each of the RF filters 306, 308 are planar filters that include one or more inductors. In the example shown, the RF filters 306, 308 respectively include inductors 310, 312. The inductors 310, 312 are disposed in a single layer and include conductive elements that may wind in any pattern in that layer. The conductive elements of the inductors 310, 312 are connected at first ends to vias 314, 316 and at second ends to conductive elements 318, 320. The vias 314, 316 are connected to conductive elements 322, 324. Portions 322A, 324A of conductive elements 322, 324 are connected to the vias 314, 316 and angle inward towards portions 322B, 324B, which extend in a support column 325.

The dielectric layers of the substrate support 300 may be formed of one or more ceramic compositions and may include, for example, aluminum nitride (AlN₃), aluminum oxide (Al₂O₃), and/or aluminum oxynitride (AlON). The conductive elements of the inductors 310, 312, the vias 314, 316 and the conductive elements 322, 324 may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys. The conductive elements 318 and 322 are connected to a first capacitor 326 and the conductive elements 320 and 324 are connected to a second capacitor 328.

Conductive portions of the capacitors 326, 328 may be formed of copper. The capacitors 326, 328 perform as RF filters and are disposed in a RF filter box 330 and are connected in parallel with the inductors 310, 312. The capacitors 326, 328 and the inductors 310, 312 receive power from the power source 144.

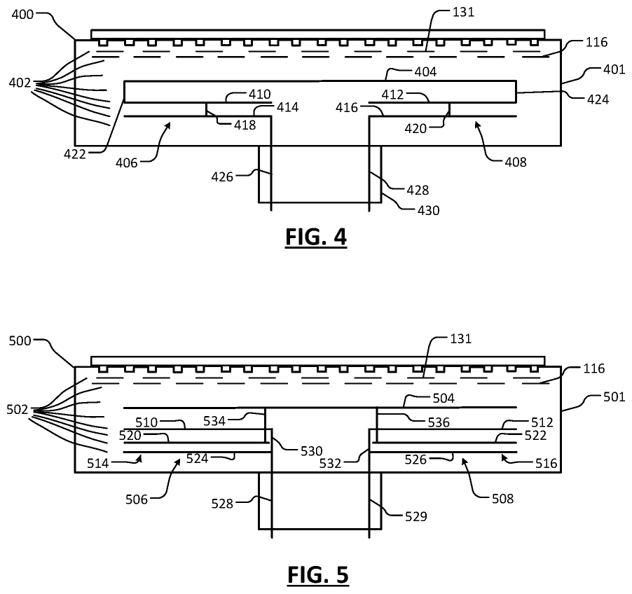

FIG. 4 shows a substrate support 400 including conductive elements of RF filters implemented in two layers. The substrate support 400 includes a body 401 having multiple layers, some of which are identified with numerical designator 402. The layers 402 include the electrodes 116, 131, a heating element 404, and the RF filters 406, 408. Dielectric material is disposed between the electrodes 116, 131, the heating element 404, and conductive elements of the RF filters 406, 408, similar to that of the substrate support 101 of FIG. 2. The heating element 404 is implemented in a single layer and may have any winding pattern. The heating element 404 may have a similar winding as the heating element of FIG. 6 or other winding pattern.

Each of the RF filters 406, 408 include one or more inductors and/or one or more capacitors. In the example shown, the RF filters 406, 408 include corresponding ones of inductors 410, 412, 414, 416. The inductors 410, 412, 414, 416 include windings having any pattern and disposed in corresponding layers. The inductors 410 and 412 are in a first layer and the inductors 414 and 416 are in a second layer. The inductors 410, 412 are connected to inductors 414, 416 by vias 418, 420. The conductive elements of the inductors 410, 414 may be connected in series. Similarly, the conductive elements of the inductors 412, 416 may be connected in series. By being disposed in respective overlapping layers, the inductors 410 and 414, in addition to having a corresponding inductance, have an associated first capacitance and function collectively as a first capacitor. Similarly, the inductors 412 and 416, in addition to having a corresponding inductance, have an associated second capacitance and function collectively as a second capacitor. The inductors 410, 412 are connected to the heating element 404 by vias 422, 424. The inductors 412, 416 are connected to conductive elements 426, 428 that extend through support column 430.

The dielectric layers of the substrate support 400 may be formed of one or more ceramic compositions and may include, for example, aluminum nitride (AlN₃), aluminum oxide (Al₂O₃), and/or aluminum oxynitride (AlON). The conductive portions of the inductors 410, 412, the vias 418, 420, 422, 424 and the conductive elements 426, 428 may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys.

FIG. 5 shows a substrate support 500 including conductive elements of RF filters implemented in three layers. The substrate support 500 includes a body 501 having multiple layers, some of which are identified with numerical designator 502. The layers 502 include the electrodes 116, 131, a heating element 504, and the RF filters 506, 508. Dielectric material is disposed between the electrodes 116, 131, the heating element 504, and conductive elements of the RF filters 506, 508, similar to that of the substrate support 101 of FIG. 2. The heating element 504 is implemented in a single layer and may have any winding pattern. An example of the heating element 504 is shown in FIG. 6.

Each of the RF filters 506, 508 include one or more inductors and/or one or more capacitors. In the example shown, the RF filters 506, 508 include corresponding ones of inductors 510, 512 (referred to as an inlet inductor 510 and an outlet inductor 512) and capacitors 514, 516. The inductors 510, 512 are implemented in a single layer. The capacitors 514, 516 are implemented in multiple layers including a first conductive layer including first conductive elements 520, 522 and a second conductive layer including second conductive elements 524, 526.

A first end of the first inductor 510 and the second conductive element 524 are connected to a first end of the heating element 504. A second end of the inductor 510 and the first conductive element 520 are connected to a conductive element 528. The first end of the first inductor 510 is connected to the second conductive element 524 and the conductive element 528 by a via 530. The second end of the first inductor 510 is connected to the first conductive element 520 by a via 534.

A first end of the second inductor 512 and the second conductive element 526 are connected to a second end of the heat element 504. A second end of the second inductor 512 and the first conductive element 522 are connected to a conductive element 529. The first end of the second inductor 512 is connected to the second conductive element 526 and the conductive element 529 by a via 532. The second end of the second inductor 512 is connected to the first conductive element 522 by a via 536. An example of the inductors 510, 512 are shown in FIG. 6.

The dielectric layers of the substrate support 600 may be formed of one or more ceramic compositions and may include, for example, aluminum nitride (AlN₃), aluminum oxide (Al₂O₃), and/or aluminum oxynitride (AlON). The conductive portions of the inductors 510, 512, the capacitors 514, 516, vias 530, 532, 534, 536 and conductive elements 520, 522, 524, 526, 528, 529 may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys.

FIG. 6 is a cross-sectional top view of a portion of the substrate support 500 illustrating an example of the heating element 504 and the inlet and outlet inductors 510, 512. Vias 530, 532, 534, 536 are shown. Although a single winding pattern is shown for each of the heating element 504 and the inductors 510, 512, other winding patterns may be implemented.

By including integrated RF filters in the substrates supports, the above provided examples minimize RF coupling to the heating elements and prevent RF coupling current from being sent from the substrate supports to the grounds and/or power outputs of the power sources providing power to the heating elements. This allows the RF power supplied to, for example, RF electrodes and clamping electrodes of the substrate support to more efficiently be provided to plasma rather than being sent to the power sources of the heating elements. This also prevents degradation to the heating elements. The RF coupling between electrodes and heating elements can degrade the heating elements over time.

By integrating RF filters in substrate supports, the above provided examples reduce the amount of space external to substrate support utilized for RF filter components. The integrated RF filters have less RF radiation variability and provide increased reliability and repeatability over traditional substrate support and RF filter box configurations.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support comprising:
a body configured to support a substrate;
a heating element at least partially implemented in a first portion of the body;
a first radio frequency filter connected to an input of the heating element and at least partially implemented in a second portion of the body and connected to the heating element by a first via; and
a second radio frequency filter connected to an output of the heating element and at least partially implemented in the second portion or a third portion of the body.

2. The substrate support of claim 1, wherein:
the first portion is a first one or more layers of the body;
the second portion is a second one or more layers of the body; and
the third portion is a third one or more layers of the body.

3. The substrate support of claim 1, wherein:
the first radio frequency filter is configured to filter out one or more radio frequencies;
the second radio frequency filter is configured to filter out the one or more radio frequencies.

4. The substrate support of claim 1, wherein:
the first radio frequency filter is configured to filter out a first one or more radio frequencies;
the second radio frequency filter is configured to filter out a second one or more radio frequencies; and
the first one or more radio frequencies are not exclusive of the second one or more radio frequencies.

5. The substrate support of claim 1, wherein:
the first radio frequency filter comprises a first inductor; and
the second radio frequency filter comprises a second inductor.

6. The substrate support of claim 5, wherein the first inductor and the second inductor are formed of at least one of a nickel alloy, a platinum alloy, a rhodium alloy, an iridium alloy, a gold nickel alloy, a copper nickel alloy, a copper tungsten alloy or a palladium alloy.

7. The substrate support of claim 5, wherein:
the first radio frequency filter has a first capacitance; and
the second radio frequency filter has a second capacitance.

8. The substrate support of claim 7, wherein:
the first radio frequency filter comprises a first capacitor having the first capacitance, the first capacitor is connected in parallel with the first inductor; and
the second radio frequency filter comprises a second capacitor having the second capacitance, where the second capacitor is connected in parallel with the second inductor.

9. The substrate support of claim 7, wherein:
the first inductor is connected in parallel with a first capacitor, which is disposed external to the substrate support; and
the second inductor is connected in parallel with a second capacitor, which is disposed external to the substrate support.

10. The substrate support of claim 7, further comprising:
a third inductor connected to the first inductor, wherein the first inductor and the third inductor are arranged to have the first capacitance; and
a fourth inductor connected to the second inductor, wherein the second inductor and the fourth inductor are arranged to have the second capacitance.

11. The substrate support of claim 7, wherein:
the first radio frequency filter comprises a first capacitor having the first capacitance;
the second radio frequency filter comprises a second capacitor having the second capacitance;
the first capacitor includes multiple conductive elements implemented in two layers of the body; and
the second capacitor includes multiple conductive elements implemented in two layers of the body.

12. The substrate support of claim 1, wherein the body comprises a clamping electrode and a radio frequency electrode.

13. The substrate support of claim 1, wherein the first radio frequency filter comprises a first capacitor and the second radio frequency filter comprises a second capacitor.

14. The substrate support of claim 13, wherein the first capacitor and the second capacitor are formed of at least one of a nickel alloy, a platinum alloy, a rhodium alloy, an iridium alloy, a gold nickel alloy, a copper nickel alloy, a copper tungsten alloy or a palladium alloy.

15. A system comprising:
the substrate support of claim 1; and
a power source supplying power to the heating element and connected to the heating element, the first radio frequency filter and the second radio frequency filter by conductive elements.

16. The system of claim 15, further comprising a filter box comprising a first capacitor and a second capacitor, wherein:
the first radio frequency filter comprises a first inductor;
the second radio frequency filter comprises a second inductor;
the first capacitor is connected to the input of the heating element and the first inductor by a first via; and
the second capacitor is connected to the output of the heating element and the second inductor by a second via.

17. A system comprising
a substrate support comprising
a plurality of layers,
a first heating element implemented in a first one or more of the plurality of layers,
a first radio frequency filter implemented in a second one or more of the plurality of layers, and
a second radio frequency filter implemented a third one or more of the plurality of layers,
wherein the first radio frequency filter, the heating element and the second radio frequency filter are connected in series; and
a power source supplying power to the first radio frequency filter to heat the substrate support,
wherein the power source receives return power back from the second radio frequency filter.

18. The system of claim17, wherein:
the substrate support further comprises
a second heating element,
a third radio frequency filter, and
a fourth radio frequency filter; and
the second heating element, the third radio frequency filter and the fourth radio frequency are connected in series and receive power from the power source.

19. The system of claim 17, wherein the second one or more of the plurality of layers is not exclusive of the third one or more of the plurality of layers.

20. The system of claim 17, wherein the first radio frequency filter and the second radio frequency filter are implemented in only one of the plurality of layers of the substrate support.

21. The system of claim 17, wherein the first radio frequency filter and the second radio frequency filter are implemented in three or five of the plurality of layers.
